(19) United States
(12) Patent Application Publication
(10) Pub. No.: US 2025/0386623 A1
(43) Pub. Date: Dec. 18, 2025

(54) SEMICONDUCTOR LIGHT EMITTING DEVICE, BONDED STRUCTURE, AND METHOD FOR PRODUCING SEMICONDUCTOR LIGHT EMITTING DEVICE

(71) Applicant: Stanley Electric Co., Ltd., Tokyo (JP)

(72) Inventors: Kyotaro KOIKE, Tokyo (JP); Ji-Hao LIANG, Tokyo (JP); Kaori TACHIBANA, Tokyo (JP)

(21) Appl. No.: 18/878,273

(22) PCT Filed: Jun. 1, 2023
(86) PCT No.: PCT/JP2023/020551

§ 371 Date: Dec. 23, 2024

(30) Foreign Application Priority Data
Jun. 23, 2022 (JP) 2022-101274

(51) Int. Cl. H10H 20/857; H10H 20/01; H10H 20/85

(52) U.S. Cl. CPC H10H 20/857; H10H 20/0364; H10H 20/8504

(57) ABSTRACT

A semiconductor light emitting device is provided which has high reliability of a bonded surface despite having a structure in which a submount substrate on which a light emitting element is mounted is ultrasonically bonded to a metal substrate. The semiconductor light emitting device includes a light emitting element, a submount substrate formed of ceramic on which the light emitting element is mounted, and a mount substrate formed of metal on which the submount substrate is mounted. The submount substrate includes a metal layer on a bonded surface with the mount substrate. The metal layer of the submount substrate is directly bonded to the mount substrate without involving a bonding material. Voids are contained in the bonded surface. A content ratio of voids is greater in a central region within a main plane of the bonded surface than in a peripheral region.

### PRIORITY AND INCORPORATION BY REFERENCE

This application is a U.S. National Stage Application under 35 U.S.C § 371 of International Patent Application No. PCT/JP2023/020551 filed Jun. 1, 2023, which claims the benefit of priority under 35 U.S.C. § 119 to Japanese Patent Application No. 2022-101274, filed Jun. 23, 2022, the content of which are incorporated herein by reference.

### TECHNICAL FIELD

The present invention relates to a semiconductor light emitting device having a structure in which a submount substrate on which a semiconductor light emitting element is mounted is directly bonded to a metal substrate.

### BACKGROUND ART

In the related art, semiconductor light emitting devices in which submount substrates on which light emitting elements are die-bonded are mounted on mount substrates formed of metal with good thermal conductivity have been known. In submount substrates, it is general to provide metal layers on upper and lower surfaces of ceramic substrates such as aluminum nitride. In mount substrates formed of metal, wiring patterns are formed on the surfaces of metal substrates via insulating layers. When submount substrates are mounted on the mount substrates formed of metal, adhesives with high thermal conductivity (solders, metal bumps, or thermally conductive adhesive containing metal fillers) are used.

In the case of solder bonding, for example, a solder material is printed in a predetermined pattern on a metal substrate, a submount substrate is set on the solder material, and a bonded portion is formed through a heating process (230° C. to 260° C.) in a reflow furnace or the like.

In the case of metal bump bonding, for example, gold balls of about 10 μm to 100 μm are ultrasonically bonded to a metal substrate at intervals of 10 μm to 100 μm or more. Thereafter, the submount substrate is set on the gold balls, and bump bonding is performed with ultrasonic waves.

In the case of bonding with silver filler resin, the silver filler resin is printed on a metal substrate, a submount substrate is set on the silver filler resin, and thermal curing (50° C. to 150° C., for about 2 hours) is performed for bonding.

As in PTL 1 and PTL 2, ultrasonic bonding technique of directly bonding two metal materials without using adhesives are known. PTL 3 discloses a technique for ultrasonically bonding electrode pads of a bare-chip light emitting element to pattern electrodes of a submount substrate. PTL 4 discloses a technique for ultrasonically bonding a lid material and a frame of a package that seals a light emitting element.

### CITATION LIST

### Patent Literature

PTL 1: JP1999-010362A
PTL 2: JP2010-023052A
PTL 3: JP2022-065415A
PTL 4: JP2022-018490A

### SUMMARY OF INVENTION

### Technical Problem

When solder bonding is used to bond a submount substrate on which a light emitting element is die-bonded to a metal substrate, an inclined angle occurs on a light emitting surface due to a solder thickness distribution of a bonded portion, which results in a defective product. When a solder thickness is thin (for example, less than 100μ), crack resistance of the solder deteriorates and thermal shock is not endured, which causes fracture of a solder bonding portion. When the solder thickness increases, thermal resistance increases. There is also a possibility that a light emitting unit of the light emitting element is contaminated by an anti-oxidation agent (flux) contained in the solder.

When gold bumps are used to bond a submount substrate to a metal substrate, a bonded portion becomes thick. Thermal resistance increases due to spaces between the bumps. Since the gold bumps are expensive and a device that bonds the bumps is also expensive, there is also problem that manufacturing cost increases.

When metal filler resin is used to bond a submount substrate to a metal substrate, thermal conductivity of a bonding material is low, and thus thermal resistance at a bonded portion increases. Since the metal filler resin is in liquid form, a variation in a thickness of an adhesive layer occurs, and thus there is also a problem that thermal resistance of the bonded portion becomes greatly irregular. The thickness of the bonded portion may become non-uniform in an in-plane direction and an inclined angle may occur in a light emitting surface, which results in a defective product.

When ultrasonic bonding can be used to bond a submount substrate to a metal substrate, both the submount substrate and the metal substrate are directly bonded and a bonding material is not necessary. Therefore, problems such as deterioration of thermal conductivity do not occur.

However, when ultrasonic bonding is used to bond a submount substrate in which a light emitting element is mounted in advance to a metal substrate, a light emitting element may be damaged due to a force applied to the light emitting when pressing the submount substrate against the metal substrate by an ultrasonic tool.

Meanwhile, when only the submount substrate is bonded to the metal substrate by ultrasonic bonding and then the light emitting element is die-bonded to the submount substrate, a bonded surface between the submount substrate and the metal substrate is likely to be fractured due to high-temperature heating during the die-bonding of the light emitting element because a thermal expansion coefficient is significantly different between the metal substrate and a ceramic substrate configuring the submount substrate. A eutectic point of AuSn eutectic is higher than a temperature range in which a manufacturer guarantees performance of the mount substrate. Therefore, the AuSn eutectic cannot be used as a die-bonding material.

Even when the problem that a force is applied to the light emitting element is solved and the submount substrate on which the light emitting element is mounted is ultrasonically bonded to the metal substrate, cracks easily occur on the bonded surface due to heat generated by the light emitting element during use because of a significant difference in thermal expansion coefficient between the ceramic substrate and the metal substrate.

In the technique for the ultrasonic bonding in PTL 3, since bare-chip electrode pads in which a bonding area is small are used, a pressure applied to the bare chip is also small. Since the technique for the ultrasonic bonding in PTL 4 involves bonding for a lid member of a semiconductor package, a structure in which a pressure is not applied to the light emitting element is provided. Therefore, even when the techniques of PTL 3 and PTL 4 are used, the problem that pressure is applied to a light emitting element or the problem of fracture or cracks of the bonded surface of the submount substrate and the metal substrate cannot be solved.

An object of the present invention provides a semiconductor light emitting device which has high reliability of a bonded surface and has a structure in which a submount substrate on which a light emitting element is mounted is ultrasonically bonded to a metal substrate.

### Solution to Problem

To achieve the above object, according to an aspect of the present invention, a semiconductor light emitting device includes a light emitting element, a submount substrate formed of ceramic and on which the light emitting element is mounted, and a mount substrate formed of metal and on which the submount substrate is mounted. The submount substrate includes a metal layer on a bonded surface with the mount substrate. The metal layer of the submount substrate is directly bonded to the mount substrate without involving a bonding material and voids are contained in the bonded surface. A central region within a main plane of the bonded surface is greater than a peripheral region.

### Advantageous Effects of Invention

The semiconductor light emitting device according to the present invention has a structure in which the submount substrate on which the light emitting element is mounted is ultrasonically bonded to the metal substrate and the voids are contained in the central region of the bonded surface. Therefore, thermal stress can be relaxed and reliability is high.

### BRIEF DESCRIPTION OF DRAWINGS

FIGS. 1(a) and 1(b) are sectional views illustrating a semiconductor light emitting device according to an embodiment and FIG. 1(c) is a diagram illustrating a distribution of voids in a bonded surface 40.

FIG. 2 is a flowchart illustrating a process of manufacturing the semiconductor light emitting device according to the embodiment.

FIGS. 3(a) to 3(g) are sectional views illustrating the process of manufacturing the semiconductor light emitting device according to the embodiment.

FIG. 4(a) is an enlarged view illustrating the process of FIG. 3(d) and FIGS. 4(b) and 4(c) are a top view and a sectional view illustrating a fixture 50.

FIG. 5 is a diagram illustrating a pressure distribution of an ultrasonic bonding process according to the embodiment.

FIG. 6 is a diagram illustrating a metal bonding process by ultrasonic waves.

FIGS. 7(a) and 7(b) are diagrams illustrating images in which a bonded surface of the semiconductor light emitting device according to the embodiment is captured by an ultrasonic microscope and FIG. 7(c) is a graph illustrating a change in ultrasonic reflectivity of the bonded surface of the semiconductor light emitting device according to the embodiment.

FIG. 8 is a diagram illustrating a cross-sectional photograph of the semiconductor light emitting device according to the embodiment.

FIG. 9(a) is a diagram illustrating a simulation model of thermal stress of the semiconductor light emitting device according to the embodiment, FIG. 9(b) is a diagram illustrating a distribution of thermal stress of the simulation result, and FIG. 9(c) is a graph illustrating a relation between a thermal stress relaxation effect and a content rate of voids.

FIG. 10 is a sectional view illustrating an ultrasonic bonding process according to a modification of the embodiment.

### DESCRIPTION OF EMBODIMENTS

A semiconductor light emitting device according to an embodiment of the present invention will be described below.

### Embodiment

### <Configuration of Semiconductor Light Emitting Device>

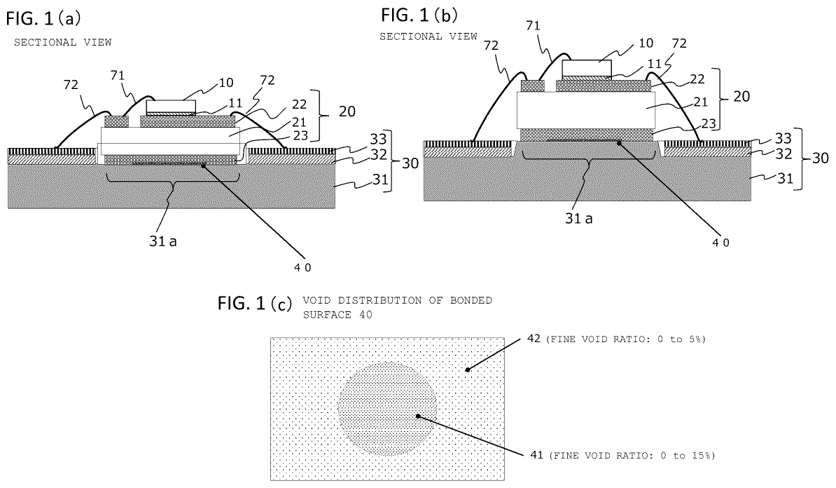

A configuration of the semiconductor light emitting device according to the embodiment will be described with reference to FIG. 1. FIGS. 1(a) and 1(b) are sectional views illustrating the semiconductor light emitting device according to the embodiment. FIG. 1(a) illustrates an example in which the upper surface of a metal substrate 31 is a flat surface and FIG. 1(b) illustrates an example in which the upper surface of the metal substrate 31 has a stepped difference. FIG. 1(c) is a diagram illustrating a distribution of voids in a bonded surface.

In the semiconductor light emitting device according to the embodiment, a light emitting element 10 is bonded onto a submount substrate 20 having a ceramic substrate serving as a base, and the lower surface of the submount substrate 20 is bonded to a mount substrate 30.

### (Submount Substrate 20)

The submount substrate 20 includes a ceramic substrate 21 serving as a base, a pair of wiring patterns 22 disposed on the upper surface of the ceramic substrate 21, and a rear surface metal layer 23 disposed on the entire lower surface of the ceramic substrate 21. The light emitting element 10 is die-bonded on the upper surface of the wiring pattern 22 by an element bonding material 11. As the ceramic substrate 21, a substrate formed of a material with good thermal conductivity (for example, AlN, SiN, Al₂O₃, or the like) is used. As the rear surface metal layer 23, a metal film having good thermal conductivity and good adhesion to the ceramic substrate 21, and in which metal on the outermost surface has hardness about equal to or lower than that of the metal substrate 31 of the mount substrate 30 is preferable. As the element bonding material 11, a conductive paste, a solder bonding material, or a eutectic bonding material such as AuSn can be used.

For example, a metal stacked film in which Cu layer/N layer/Pd layer/Au layer are stacked in this order from the ceramic substrate 21 side is used. The Au layer on the outermost surface has hardness about equal to that of the metal substrate 31 of the mount substrate 30. Here, the outermost surface is not limited to the Au layer, and metal with high corrosion resistance is preferable. For example, in the case of Cu layer/Ni layer/(Pd layer)/Au layer, film thickness can be set to 50 μm/4 μm/0.1 μm/0.1 μm, respectively.

Here, the ceramic substrate 21 is used, and a sapphire substrate, a silicon (Si) substrate, a substrate gallium nitride (GaN) substrate, a carbon nitride (Sic) substrate, or the like can also be used.

### (Mount Substrate 30)

The mount substrate 30 has a structure in which an insulating layer 32 is provided on the surface of the metal substrate 31 serving as a base and a circuit pattern 33 is mounted on the insulating layer 32. For the metal substrate 31, metal with good thermal conductivity (for example, an Al substrate, a Cu substrate, or the like) is used. In the metal substrate 31, a mounting region 31a on which the submount substrate 20 is mounted is set, the insulating layer 32 and the circuit pattern 33 are not provided in the mounting region 31a, and the upper surface of the metal substrate 31 is exposed. In the metal substrate 31, as in FIG. 1(a), the upper surface may be a flat surface, or as in FIG. 1(b), the upper surface of the mounting region 31a may be higher than the peripheral region by a thickness of the insulating layer 32 and the circuit pattern 33.

The insulating layer 32 is formed of a material capable of insulating the circuit pattern 33 from the metal substrate 31 at a predetermined withstand voltage. The material of the insulating layer 32 has a considerably lower thermal conductivity than metal or the like. For example, the insulating layer 32 obtained by processing a material called a prepreg, in which thermosetting resin such as epoxy is evenly impregnated in a fiber reinforcing material and made to be a semi-cured state, into a predetermined pattern, mounting the prepreg on the metal substrate 31, and then curing the prepreg is used. The circuit pattern 33 is formed of metal with low electrical resistance (for example, Cu).

### (Bonded Surface 40)

The submount substrate 20 is mounted in the mounting region 31a of the metal substrate 31, the lower surface of the rear surface metal layer 23 of the submount substrate 20 is directly bonded to the upper surface of the metal substrate 31 by ultrasonic bonding without involving a bonding material. That is, the metal of the lowermost surface of the rear surface metal layer 23 of the submount substrate 20 is metal-to-metal bonded to the metal substrate 31 by interatomic forces between dissimilar metals without using an adhesive material. Here, Au of the rear surface metal layer 23 on the submount substrate 20 side is metal-to-metal bonded to Al of the metal substrate 31. That is, an interface between the bottom surface of the submount substrate 20 and the upper surface of the mount substrate 30 configures a bonded surface. Specifically, an interface between the entire lower surface of the rear surface metal layer 23 and the upper surface of the metal substrate 31 configures the bonded surface.

A combination of the rear surface metal layer 23 and the metal substrate 31 on the bonded surface may be any metal except for hard metal (for example, Ni or the like) on the outermost bonded surface. In addition to Al—Au bonding, for example, Al—Al bonding, Cu—Au bonding, Au—Au bonding, or the like can be used.

### (Void)

The bonded surface 40 between the lower surface of the rear surface metal layer 23 of the submount substrate 20 and the upper surface of the metal substrate 31 is subjected to ultrasonic bonding so that fine voids are contained in the bonded interface.

A size of the voids is preferably 5 μm or less or particularly 1 μm or less on average.

A content of the voids per unit area in the bonded surface 40 differs depending on a position on a main plane of the bonded surface 40. A central region 41 of the bonded surface 40 contains more voids than a peripheral region 42.

Specifically, the content of the voids is 5% or more and 15% or less per unit area in the central region 41, and is 0% or more and 5% or less per unit area in the peripheral region. In particular, the content of the voids is preferably 1.0% or more and 15% or less per unit area in the central region 41, and is 0% or more and 5% or less in the peripheral region 42.

In a top view of the light emitting element 10, the central region 41 includes a bottom surface region of the light emitting element 10.

A distance from the central region 41 to an edge of the bonded surface 40 (an edge of the submount substrate 20) is preferably in the range of 5% to 30% of longitudinal and transverse sizes of the submount substrate 20.

The size of the voids depends on surface roughness of the lower surface of the rear surface metal layer 23 and the upper surface of the metal substrate 31 before the bonding and conditions during the ultrasonic bonding. Therefore, by controlling the surface roughness and the conditions, it is possible to form the voids in the bonded surface by a size of 5 μm or less. The surface roughness of the lower surface of the rear surface metal layer 23 and the upper surface of the metal substrate 31 before the bonding is preferably Rz(23)<5 μm and Rz(31)<8 μm, and particularly preferably Rz(23)<3 μm and Rz(31)<5 μm.

More specifically, on the surface of the rear surface metal layer 23 of the submount substrate 20 and the surface of the metal substrate 31 before bonding by a bonding process, Rz (maximum height) of the surface roughness on a surface with larger surface roughness is preferably 0.5 μm or more and 5 μm or less.

A size of the central region 41 containing more voids depends on an opening area of a cavity portion provided in a fixture to not apply a pressure to the light emitting element 10 during ultrasonic bonding. The opening area has upper and lower limits because of conditions such as the size of the light emitting element 10, the size or thickness of the ceramic substrate 21, or the like. Accordingly, by obtaining such conditions in advance, the bonding can be performed so that more voids are included in the central region 41 with a desired size.

Since the shape of the central region 41 depends on an opening shape of the cavity portion of the fixture during the ultrasonic bonding, any shape such as a quadrangle may be used in addition to a circle.

The opening area or the shape of the fixture and setting conditions during the ultrasonic bonding will be described specifically below.

### <Operational Effect of Bonded Surface 40>

In the embodiment, as described above, thermal resistance on the bonded surface 40 can be minimized due to a structure in which the submount substrate 20 and the metal substrate 31 of the mount substrate 30 are directly bonded without using a bonding material for the bonded surface 40. Accordingly, heat generated by the light emitting element 10 is conducted and dissipated to the metal substrate 31 via the element bonding material 11, the submount substrate 20, and the bonded surface 40.

Since a bonding material is not used for the bonded surface 40, there is no variation in thermal resistance due to a thickness distribution of the bonding material and the heat of the light emitting element 10 can be conducted evenly from the entire bonded surface 40.

The bonded surface 40 is configured to contain voids of 5% or more and 15% or less in the central region 41 and voids of 0% or more and 5% or less in the peripheral region 42. Therefore, even when internal stress occurs on the bonded surface 40 by heat of the light emitting element 10 due to a significant difference in a thermal expansion coefficient between the ceramic substrate 21 and the metal substrate 31, stress can be relaxed by contraction or expansion of the voids. Here, since more voids are contained in the central region 41 than the peripheral region 42, stress can be relaxed in a region immediately below the light emitting element 10 in which a rise in temperature is the largest and generated stress is the largest. Since an amount of voids is less in the peripheral region 42 than in the central region 41, a contact area between the rear surface metal layer 23 of the submount substrate 20 and the metal substrate 31 of the mount substrate 30 is larger and has higher bonding strength. Accordingly, even when thermal stress is applied, the bonding is still strong and cracks are prevented from occurring.

Since the ultrasonic bonding is performed at room temperature, no intermetallic compounds are formed on the bonded surface. Since heating to a high temperature is not required, there is also an advantage that a thermal influence on the light emitting element 10 is small during the bonding.

### <Process of Manufacturing Semiconductor Light Emitting Device>

Next, a method for manufacturing the semiconductor light emitting device according to the embodiment will be described.

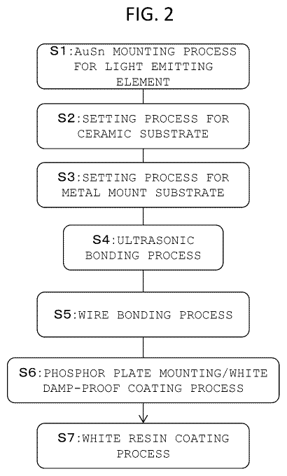

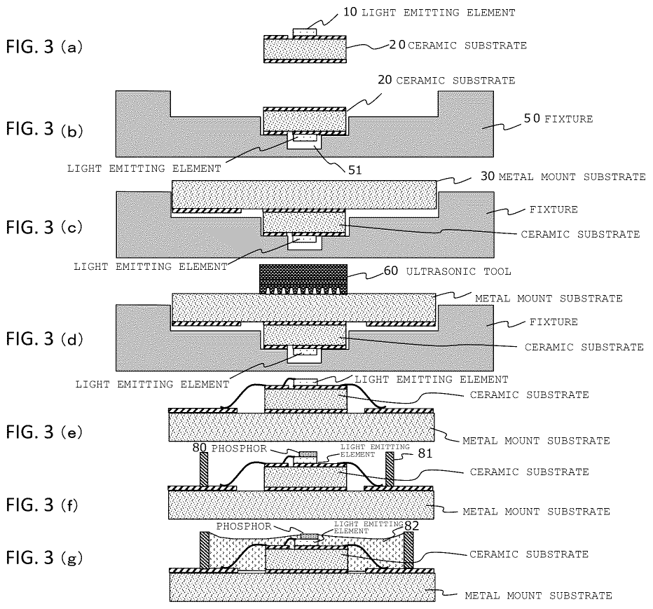

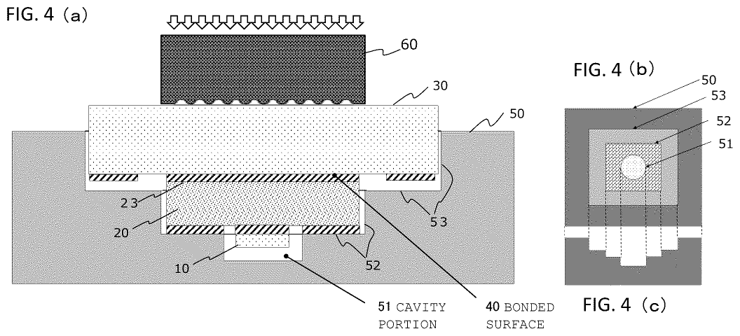

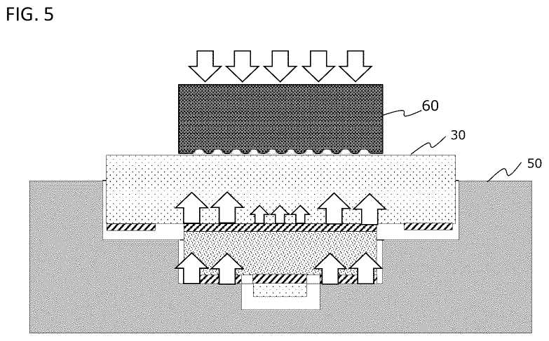

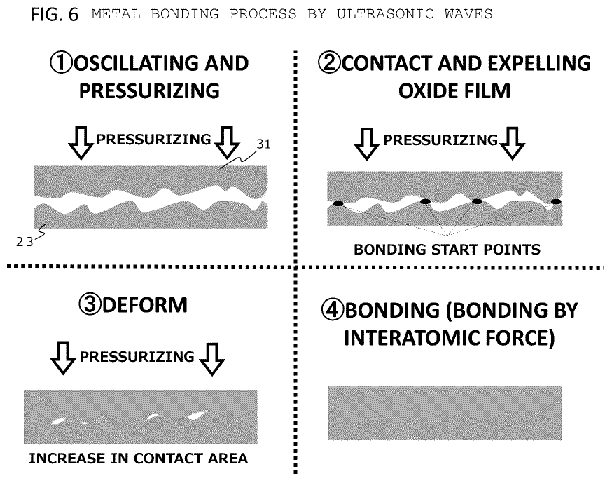

FIG. 2 is a flowchart illustrating a manufacturing process. FIGS. 3(a) to 3(g) are sectional views illustrating the manufacturing process. FIG. 4(a) is an enlarged view illustrating the process of FIG. 3(d). FIGS. 4(b) and 4(c) are a top view and a sectional view illustrating a fixture 50. FIG. 5 is a diagram illustrating a pressure distribution during ultrasonic bonding. FIG. 6 is a diagram illustrating a metal bonding process by ultrasonic waves.

### (Step S1)

First, as in FIG. 3(a), the light emitting element 10 is mounted (die-bonded) on the wiring pattern 22 on the upper surface of the submount substrate 20 using the AuSn eutectic as the element bonding material 11.

### (Step S2)

As in FIG. 3(b), the submount substrate 20 is set in the fixture 50 so that the upper surface of the light emitting element 10 is oriented downward.

In the fixture 50, a cavity portion 51 for accommodating the light emitting element 10 is provided at the center, a first stepped portion 52 for accommodating and supporting the submount substrate 20 is provided on the outer side of the cavity portion 51, and a second stepped portion 53 accommodating the mount substrate 30 is provided on the further outer side (see FIGS. 3(b) and 4(a) to 4(c)).

In the submount substrate 20, the light emitting element 10 is already mounted in step S1. When the submount substrate 20 is mounted in the first stepped portion 52 of the fixture 50, the light emitting element 10 is accommodated in the cavity portion 51 and does not come into contact with the fixture 50. Accordingly, the submount substrate 20 can be supported by the fixture 50 so that no pressure is applied to the light emitting element 10 in the process of step S4 in FIG. 3(d).

Here, to form a circular region as the central region 41 that contains more voids in the bonded surface 40 (see FIG. 1(b)), an opening shape of the cavity portion 51 is provided in a circular shape. The opening size of the cavity portion 51 is required to be greater than the size of the light emitting element 10. To support the submount substrate 20 with an area of the lower surface of the first stepped portion 52 excluding an opening of the cavity portion 51, an area for sufficiently supporting the submount substrate 20 is required to be secured in the first stepped portion 52 according to a size, a material, thickness, bonding conditions, and the like of the submount substrate 20. Accordingly, the size of the opening of the cavity portion 51 is the size of the light emitting element 10 or more and is set to be a size with which a minimum area necessary for the lower surface of the first stepped portion 52 can be secured or less.

### (Step S3)

Subsequently, as in FIG. 3(c), the mount substrate 30 is mounted on the submount substrate 20 inside the fixture 50.

### (Step S4)

Subsequently, as in FIGS. 3(d) and 4(a), an ultrasonic tool 60 is brought into contact on the mount substrate 30 and, as illustrated in FIG. 5, an ultrasonic energy is applied to the metal substrate through the ultrasonic tool 60 while pressurizing the mount substrate 30 in a direction that presses the submount substrate 20 by the ultrasonic tool 60.

Accordingly, as in (1) of FIG. 6, pressure and ultrasonic vibration from the ultrasonic tool 60 are applied to the metal substrate 31 of the mount substrate 30 and the rear surface metal layer 23 of the submount substrate 20. As in (2) of FIG. 6, friction/plastic flow occurs between the surface of the metal substrate 31 and the rear surface metal layer 23 brought into contact with the surface of the metal substrate 31. As in (3) of FIG. 6, an oxide film on the metal surface is expelled and a newly formed surface of metal is exposed. The metal substrate 31 and the rear surface metal layer 23 are deformed centering on contact portions between the exposed metals and a contact area increases, and thus the entire contact surface is bonded in a solid phase by an interatomic force as in (4) of FIG. 6. The solid-phase bonding is different from fusion bonding, and is bonding in a solid phase state near the room temperature far below a melting point of the metal material.

Here, the cavity portion 51 is provided in the fixture 50 and the first stepped portion 52 in the periphery of the cavity portion 51 supports an edge of the submount substrate 20 in which the light emitting element 10 is not provided. Therefore, in the bonded surface 40 during the bonding, as indicated by arrows in FIG. 5, a pressure applied to the central region becomes smaller than a pressure applied to the peripheral region, and a distribution of the pressure is generated. Therefore, in the peripheral region 42 of the bonded surface 40, surface unevenness of the lower surface of the rear surface metal layer 23 and the upper surface of the metal substrate 31 is deformed by pressure and ultrasonic vibration so that a contact area increases. Accordingly, voids rarely occur and strong bonding is achieved. Since the pressure in the central region 41 of the bonded surface 40 is smaller than in the peripheral region, a gap of the surface unevenness of the lower surface of the rear surface metal layer 23 and the upper surface of the metal substrate 31 partially remains and becomes voids.

Accordingly, it is possible to form the bonded surface 40 configured by the central region 41 containing more voids and the peripheral region 42 containing less voids.

A vibration mode of the ultrasonic tool 60 may be rectilinear vibration, or ultrasonic composite vibration (circular or elliptical vibration generated by adding torsional vibration to rectilinear vibration) is more suitable because pressure is more easily applied to an outer periphery of the bonded surface 40 by circular vibration and the outer periphery of the bonded surface 40 can be more strongly bonded.

### (Step S5)

Subsequently, the mount substrate 30 and the submount substrate 20 which are extracted from the fixture 50. As in FIG. 3(e), an upper surface electrode of the light emitting element 10 and one of the pair of wiring patterns 22 of the submount substrate 20 are connected with a wire 71 by wire bonding. The pair of wiring patterns 22 and the circuit pattern 33 on the mount substrate 30 are respectively connected with one pair of wires 72 by wire bonding.

When the light emitting element 10 is a flip-chip element, the wire 71 is unnecessary. When the light emitting element 10 includes two upper surface electrodes, the upper surface electrodes of the light emitting element 10 are respectively connected to the pair of wiring patterns 22 by two wires 71.

### (Step S6)

Subsequently, as in FIG. 3(f), a phosphor plate 80 is mounted on the upper surface of the light emitting element 10 and a frame 81 having a light-reflective property is mounted on the mount substrate 30 separated from the submount substrate 20 by a predetermined distance.

### (Step S7)

Finally, as in FIG. 3(g), the inside of the frame 81 is filled with sealing resin 82 in which light-reflective fillers are dispersed and the sealing resin 82 is cured so that the light emitting element 10 and the submount substrate 20 are buried except for the upper surface of the phosphor plate 80.

As such, the semiconductor light emitting device can be manufactured.

Steps S6 and S7 may be performed as necessary.

Any surface-uneven structure can be provided on the surface of the ultrasonic tool which comes into contact with the mount substrate 30 and the surface of the first stepped portion 52 of the fixture 50 which comes into contact with the submount substrate 20. Accordingly, ultrasonic energy can be efficiently applied to the bonded surface 40. Here, the uneven structure is transferred to each surface of the submount substrate 20 or the mount substrate 30 with which the uneven structure comes into contact.

The semiconductor light emitting device and the manufacturing method therefor according to the embodiment have been described assuming that the number of light emitting elements 10 is one, but a plurality of light emitting elements may be disposed on the submount substrate. Then, during the setting in the fixture in step S2, the plurality of light emitting elements can be accommodated in one cavity portion or the light emitting elements may be appropriately accommodated in a plurality of cavity portions.

### EXAMPLE

As an example, a semiconductor light emitting device was manufactured according to the manufacturing method of the above-described embodiment.

### (Mount Substrate 30)

As the mount substrate 30, a substrate in which a material of the metal substrate 31 was Al and a size was 36 mm×36 mm×2.0 mmt was used.

### (Submount Substrate 20)

As the submount substrate 20, a substrate in which a material of the ceramic substrate 21 was AlN, the outermost surface of the rear surface metal layer 23 was Au, and a size is 3.0 mm×4.0 mm×0.48 mmt was used.

### (Ultrasonic Tool)

The ultrasonic tool 60 was formed of a tool steel, and a contact area with the mount substrate 30 was about equal to an area of the bonded surface 40 or more. On the surface of the mount substrate 30 with which the ultrasonic tool 60 comes into contact, knurling treatment (periodic fine unevenness) was used as an anti-slip surface treatment.

### (Fixture 50)

As the fixture 50, a fixture formed of a stainless steel (pre-hardened) was used. The first stepped portion 52 of the fixture 50 supporting the submount substrate 20 may be subjected to knurled treatment similar to the ultrasonic tool 60.

A diameter of the opening of the cavity portion 51 of the fixture 50 was set to φ1.8 mm. The size of the light emitting element 10 was about 1 mm square.

### (Bonding Conditions)

An ultrasonic mode was set to a composite vibration, frequency: 20 kHz, static pressure: 2000 N or less, oscillation time: 2.0 sec or less, and AMPL (a current ratio corresponding to vibration amplitude): 100% or less.

Specifically, frequency: 20 KHz, AMPL: 10 to 80% (0 to 100%), static pressure: 100 to 1000 N (0 to 2000 N), and oscillation time: 0.1 to 2.0 sec (0 to 5.0 sec).

### <Cross-Sectional Photograph of Bonded Surface 40>

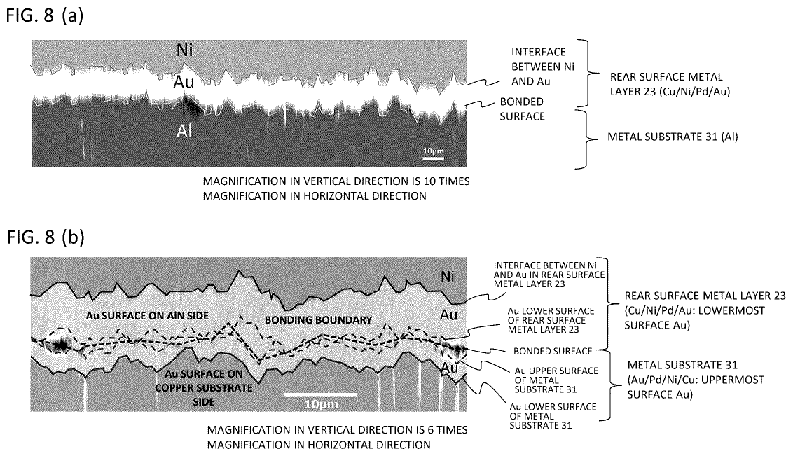

FIGS. 8(a) and 8(b) illustrate cross-sectional photographs of the bonded surface 40 obtained in the example.

FIG. 8(a) is a sectional view illustrating a bonded surface subjected to ultrasonic bonding using an Al substrate as the metal substrate 31 and using a stacked film of Cu/Ni/Pd/Au (outermost layer: Au layer) as the rear surface metal layer 23.

Referring to FIG. 8(a), the surface of the metal substrate (Al substrate) 31 has a bonded surface similar to surface unevenness of the Au layer of the rear surface metal layer 23 that is a bonding target. Here, it can be understood that, in the ultrasonic bonding, the bonded surface is formed to follow the surface shape of a layer with higher hardness (the Au layer of the rear surface metal layer 23). Accordingly, when the surface unevenness of the surface with higher hardness is too large, it is considered that voids occur because the surface with low hardness cannot fully follow the surface shape of the surface with higher hardness.

FIG. 8(b) is a sectional view illustrating a bonded surface subjected to ultrasonic bonding using a Cu substrate in which/Au/Pd/Ni is stacked on the surface (outermost layer: Au layer) as the metal substrate 31 and using a stacked film of Cu/Ni/Pd/Au (outermost layer: Au layer) as the rear surface metal layer 23.

Since the outermost surfaces of both sides of the bonded surface are Au layers, the bonded surface is formed by in-plane reconstruction of Au metal. From FIG. 8(b), it can be understood that, because of surface reconstruction of Au metal, the bonded surface is not a simple surface but is a surface repeating a portion in which the lower surface of the Au layer of the rear surface metal layer 23 comes into contact with the upper surface of the Au layer of the metal substrate 31 and a portion in which the contact is not made, and the non-contacting portion becomes a void.

From FIG. 8(b), it was confirmed that fine voids of about 5 μm or less and about 1 μm, were formed.

### <Method for Confirming Distribution of Voids>

Here, a method of obtaining an amount of voids on the bonded surface of the semiconductor light emitting device will be described.

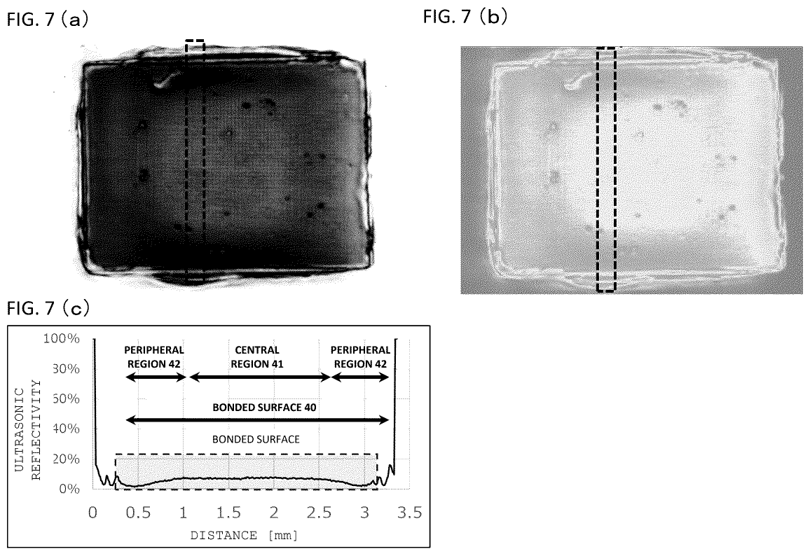

When an image of the bonded surface 40 is captured from the upper surface of the light emitting element 10 by an ultrasonic microscope (constant-depth mode scanning acoustic microscorpe (C-SAM)), an ultrasonic microscope image is an image in which a bonded portion having no void is black (low reflectivity) and a bonded portion having voids is white (high reflectivity) in the bonded surface 40 (see FIG. 7(a)). Accordingly, an amount of voids can be calculated with grayscales of the ultrasonic microscope image. FIG. 7(b) illustrates an image of the bonded surface 40 in which grayscales are adjusted. It can be understood that the central region is brighter than the peripheral region and thus has a larger amount of voids.

FIG. 7(c) is a graph illustrating reflectivity of ultrasonic waves of the bonded surface 40 obtained from the grayscales of FIG. 7(a). It is considered that the ultrasonic reflectivity on the bonded surface indicates a surface density of voids as the ultrasonic reflectivity on the outside of the bonded surface, that is, an interface region with the air, is 100%. According to the graph of FIG. 7(c), the reflectivity in the central region of the bonded surface is considerably lower than in the peripheral region and it can be understood that voids are distributed therein.

Since the ultrasonic reflectivity of the central region 41 in FIG. 7(c) is in the range of 5% to 10%, it can be assumed that the surface density of the voids in the central region 41 is in the range of 5% to 10%.

### <Thermal Stress Simulation Result>

Here, it was confirmed in a simulation that thermal stress of the bonded surface 40 can be relaxed when the amount of voids 5% or more and 15% or less per unit area is included in the central region 41 of the bonded surface 40.

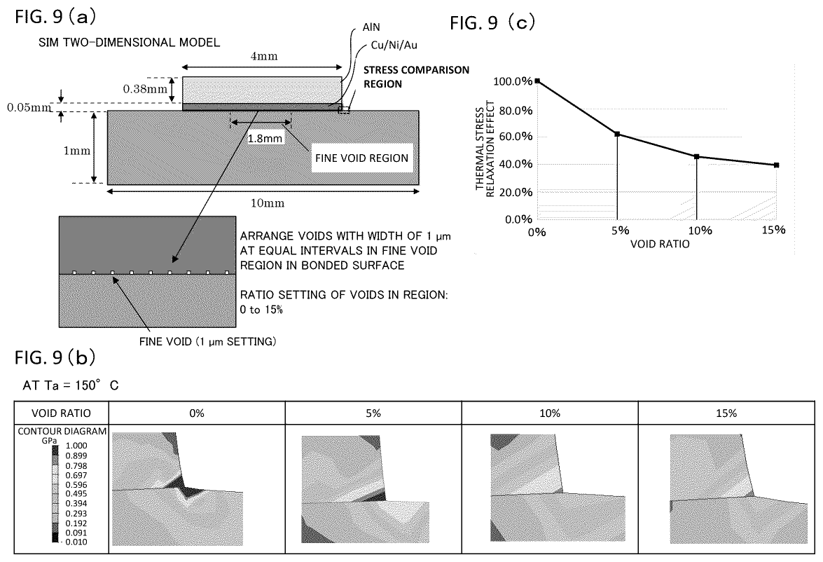

A thermal stress distribution at Ta=150° C. was calculated by a two-dimensional simple model for a model of the semiconductor light emitting element (FIG. 9(a)) in which voids with a size (width) of 1 μm were arranged at equal intervals at ratios of 5%, 10%, and 15% per unit area in the central region 41 of the bonded surface 40 and voids were not arranged in the peripheral region 42 (Ta: T [atmosphere], environmental temperature (in the periphery of the bonded portion)). A publicly known analysis simulation software (Femted (registered trademark) manufactured by Murata Manufacturing Co., Ltd.) was used. A calculation result is illustrated in FIG. 9(b).

As a comparative example, a thermal stress distribution was calculated for a model in which voids were not arranged (0%) in both the central region 41 and the peripheral region 42. A calculation result of the comparative example is also illustrated in FIG. 9(b).

A value of the thermal stress at an end portion of the bonded surface 40 in the thermal stress distribution illustrated in FIG. 9(b) is shown in the graph of FIG. 9(c). As apparent from FIG. 9(c), it can be understood that the thermal stress considerably decreases in the model in which the voids are included at the ratios of 5%, 10%, and 15% in the central region 41, compared to the comparative example in which the voids are not included (0%). As a content of the voids increases, the thermal stress decreases.

Accordingly, it was confirmed that thermal stress decreases in the structure of the bonded surface 40 in which fine voids that do not significantly affect heat conduction are formed in the central region 41 of the bonded surface 40 and no voids are e formed in the outer periphery. Accordingly, cracks are prevented from occurring in the outer periphery of the bonded surface 40 due to thermal shock and reliability is improved.

When the central region 41 that contains voids is further expanded, further thermal relaxation is expected. However, since the peripheral region 42 decreases, the bonding strength of the periphery decreases and there is concern that voids in the periphery will cause cracks. That is, since stress relaxation and cracks occurring in the outermost periphery of the bonded surface 40 have a trade-off relationship, a region size of the central region 41 is preferably set in a range in which stress relaxation and bonding strength of the outermost periphery are compatible. When considering a ratio of the voids in the central region 41 that does not affect thermal resistance, a ratio of the voids per unit area is preferably less than about 30%, and more preferably about 15% or less.

The inventors have experimentally confirmed that there is no significant change in thermal resistance even when a cavity exists immediately below the element when 70% or more of the bonded area is secured.

According to the experiment of the inventors, the size of the voids affect thermal resistance. Voids with a size of 10 μm or less do not significantly affect thermal resistance even when a ratio of the voids in the central region 41 is large. However, when the ratio of the voids in the central region 41 increases, voids with large sizes easily occur. Therefore, a ratio of the voids per unit area is preferably less than about 30% and more preferably about 15% or less, as described above.

### Modification

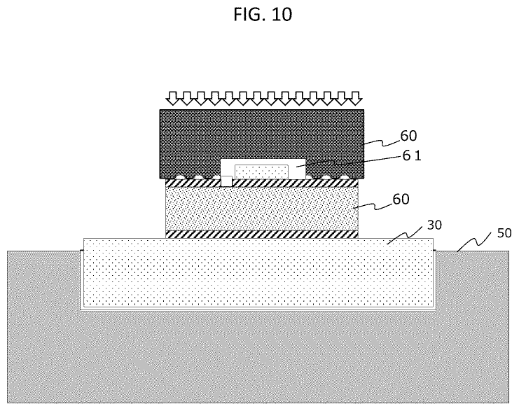

According to the above-described embodiment, in the ultrasonic bonding process of step S4 of the flow in FIG. 2, as in FIGS. 3(d) and 4(a), the ultrasonic tool 60 is pressed on the rear surface side of the mount substrate 30 and ultrasonic vibration is applied to the mount substrate 30. According to a modification, as in FIG. 10, the ultrasonic tool 60 may be pressed on the upper surface of the submount substrate 20.

Here, a cavity portion 61 that accommodates the light emitting element 10 is provided in the ultrasonic tool 60 so that the ultrasonic tool 60 does not come into contact with the light emitting element 10.

In the fixture 50, only a depression that supports the mount substrate 30 may be provided.

In the ultrasonic bonding process of FIG. 10 according to the modification, compared to the case in which the large mount substrate 30 is vibrated as in the ultrasonic bonding of FIG. 4(a), the small submount substrate 20 is vibrated, so that the bonded surface 40 can be bonded while minimizing damage to the submount substrate 20 with smaller ultrasonic energy than in FIG. 4(a). Accordingly, even when the thickness of the mount substrate 30 is thick, the ultrasonic energy can be efficiently applied to the bonded surface without the energy being attenuated.

The technique of the semiconductor light emitting device according to the embodiment can be used for a lighting fixture light source unit and a white light source module.

### REFERENCE SIGNS LIST

10: light emitting element
11: element bonding material
20: submount substrate
21: ceramic substrate
22: wiring pattern
23: rear surface metal layer
30: mount substrate
31: metal substrate
31a: mounting region
32: insulating layer
33: circuit pattern
40: bonded surface
41: central region
42: peripheral region
50: fixture
51: cavity portion
60: ultrasonic tool
61: cavity portion
71: wire
72: wire
80: phosphor plate
81: frame
82: sealing resin

1. A semiconductor light emitting device comprising: a light emitting element;
a submount substrate on which the light emitting element is mounted; and a mount substrate formed of metal on which the submount substrate is mounted, wherein
the submount substrate includes a metal layer on a bonded surface with the mount substrate,
the metal layer of the submount substrate is directly bonded to the mount substrate without involving a bonding material and voids are contained in the bonded surface, and
a content of voids per unit area in the bonded surface is greater in a central region within a main plane of the bonded surface than in a peripheral region.

2. The semiconductor light emitting device according to claim 1, wherein a surface density of the voids is 5% or more and 15% or less in the central region, and is 5% or less in the peripheral region.

3. The semiconductor light emitting device according to claim 1, wherein, in a top view of the light emitting element, the central region is larger than a bottom surface region of the light emitting element.

4. The semiconductor light emitting device according to claim 1, wherein a size of each of the voids is 5 μm or less.

5. The semiconductor light emitting device according to claim 1, wherein the metal layer provided on the bonded surface of the submount substrate with the mount substrate has hardness lower than hardbess of the mount substrate formed of metal.

6. The semiconductor light emitting device according to claim 1, wherein the mount substrate formed of metal is formed of one of Al and Cu or an alloy of Al and Cu,
the submount substrate includes a ceramic substrate serving as a base and the ceramic substrate is formed of one of AlN, SiN, and Al₂O₃, and
the metal layer is formed on the bonded surface of the ceramic substrate with the mount substrate and the metal layer is an Au layer.

7. A bonded structure comprising: a ceramic substrate having one surface on which a metal layer is formed; and a metal substrate bonded to the surface of the ceramic substrate on which the metal layer is formed, wherein
the metal layer of the ceramic substrate is directly bonded to the metal substrate without involving a bonding material and voids are contained in a bonded surface, and
a content of voids per unit area in the bonded surface is greater in a central region within a main plane of the bonded surface than in a peripheral region.

8. A method for manufacturing a semiconductor light emitting device, the method comprising:
a disposing process of overlapping a submount substrate having an upper surface on which a light emitting element is mounted and a lower surface on which a metal layer is provided with a mount substrate formed of a metal on the lower surface side of the submount substrate; and
a bonding process of being contained voids in a central region of a bonded surface while directly bonding the metal layer of the submount substrate and the bonded surface by pressing an ultrasonic tool against the upper surface of the submount substrate or a lower surface of the mount substrate and pressing a peripheral region of the submount substrate by a larger force than the central region and performing ultrasonic vibration.

9. The method for manufacturing a semiconductor light emitting device according to claim 8, wherein, between a surface of the metal layer of the submount substrate and a surface of the mount substrate formed of metal before the bonding of the bonding process, a surface with larger surface roughness has Rz (maximum height) of surface roughness of 0.5 μm or more and 5 μm or less.

10. The method for manufacturing a semiconductor light emitting device according to claim 9, wherein a film thickness of the metal layer of the submount substrate before the bonding of the bonding process is greater than a value of Rz of the surface roughness.

11. The method for manufacturing a semiconductor light emitting device according to claim 8, wherein
in the disposing process, the submount substrate is mounted on a fixture so that the light emitting element is located below the submount substrate and the upper surface of the mount substrate is mounted on the submount substrate so that the upper surface of the mount substrate comes into contact with the submount substrate,
the bonding process is a process of pressing the ultrasonic tool from above the mount substrate supported by the fixture and applying ultrasonic vibration, and
in the fixture, a cavity portion is provided for preventing the light emitting device from coming into contact with the fixture.

12. The method for manufacturing a semiconductor light emitting device according to claim 8, wherein
in the disposing process, the mount substrate is mounted on a fixture and the submount substrate is mounted on the mount substrate,
the bonding process is a process of pressing the ultrasonic tool from the upper surface of the submount substrate and applying ultrasonic vibration, and
in the ultrasonic tool, a cavity portion for preventing the light emitting device from coming into contact with the ultrasonic tool is provided.

13. The method for manufacturing a semiconductor light emitting device according to claim 11, wherein an opening size of the cavity portion of the fixture is greater than a size of the light emitting element.
